(19) United States
(12) Patent Application Publication
(10) Pub. No.: US 2009/0309208 A1
(43) Pub. Date: Dec. 17, 2009

(54) SEMICONDUCTOR DEVICE AND METHOD OF MANUFACTURING THE SAME

(75) Inventor: Yoshihiro MACHIDA, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/485,617

(22) Filed: Jun. 16, 2009

(30) Foreign Application Priority Data
Jun. 17, 2008 (JP) 2008-157524

(51) Int. Cl. H01L 23/02; H01L 21/56; H01L 21/50

(52) U.S. Cl. 257/687; 438/121; 257/E23.18; 257/E21.503; 257/E21.499

(57) ABSTRACT

A semiconductor device is provided. The semiconductor device includes: an insulating layer having an opening therethrough; a wiring pattern formed on the insulating layer; an external connection terminal provided on a portion of the wiring pattern which is exposed from the opening; a semiconductor element flip-chip-mounted on the wiring pattern through a connection portion; an underfill resin which is filled between the semiconductor element and the wiring pattern to cover the connection portion; and a sealing resin portion which seals the semiconductor element.

This application claims priority from Japanese Patent Application No. 2008-157524, filed on Jun. 17, 2008, the entire contents of which are incorporated by reference herein.

### BACKGROUND OF THE INVENTION

1. Technical Field

The present disclosure relates to a semiconductor device and a manufacturing method of the semiconductor device.

2. Related Art

In a related-art semiconductor device, a semiconductor element is mounted on a wiring board made of a glass epoxy resin or the like, on which a wiring pattern is formed, and then the semiconductor device is electrically connected to the wiring pattern.

FIGS. 9 and 10 illustrate the related-art semiconductor device. FIG. 9 is a cross-sectional view illustrating a semiconductor device 200 formed by a wire-bonding method. In FIG. 9, a semiconductor element 120 is mounted on a surface of a wiring board having a wiring pattern 116 that electrically connects a connection pad 112 formed on one side of a substrate K via a through hole 110 to an external connection terminal 114 formed on the other side thereof. An electrode pad 122 formed on the semiconductor element 120 is electrically connected to a connection pad 112 of the wiring board by a bonding wire 130. Subsequently, the semiconductor element 120 and the bonding wire 130 are sealed with a sealing resin. Further, FIG. 10 is a cross-sectional view illustrating a semiconductor device 200 formed by a flip-chip bonding method. That is, an electrode 126 (i.e., an electrode pad 122 and a bump 124) of a semiconductor element 120 is bonded to a connection pad 112 formed one surface of a wiring board. Then, an underfill resin 150 is injected between the connection pad 112 and the electrode 126.

The above semiconductor devices 200 are disclosed in, e.g., JP-A-9-97860 (the wire bonding connection method) and JP-A-2003-152001 (the flip-chip connection method).

The thickness dimension of a semiconductor device can be considerably reduced by employing the flip-chip connection method, which is illustrated in FIG. 10, instead of the wire bonding connection method, which is illustrated in FIG. 9.

In recent years, a further reduction in the thickness of semiconductor devices has been desired. The semiconductor device formed by the flip-chip connection method is reaching the limit on the reduction in the thickness thereof.

### SUMMARY OF THE INVENTION

Exemplary embodiments of the present invention address the above disadvantages and other disadvantages not described above. However, the present invention is not required to overcome the disadvantages described above, and thus, an exemplary embodiment of the present invention may not overcome any of the problems described above.

An inventor of the invention has focused attention on the fact that the thickness dimension of a semiconductor device can be reduced by not using a substrate which supports a wiring pattern. Accordingly, it is an aspect of the invention to provide a semiconductor device which can easily be handled in a manufacturing process thereof even in the case of omitting a substrate, and to provide a manufacturing method thereof.

According to one or more aspects of the present invention, there is provided a semiconductor device. The semiconductor device comprises: an insulating layer having an opening therethrough; a wiring pattern formed on the insulating layer; an external connection terminal provided on a portion of the wiring pattern which is exposed from the opening; a semiconductor element flip-chip-mounted on the wiring pattern through a connection portion; an underfill resin which is filled between the semiconductor element and the wiring pattern to cover the connection portion; and a sealing resin portion which seals the semiconductor element.

According to one or more aspects of the present invention, there is provided a method of manufacturing a semiconductor device. The method comprises: (a) providing a metal foil; (b) laminating a first carrier tape on the metal foil; (c) forming an insulating layer on the metal foil; (d) forming an opening through the insulating layer; (e) laminating a second carrier tape on the insulating layer; (f) removing the first carrier tape; (g) etching the metal foil to form a wiring pattern; (h) providing an underfill resin on the wiring pattern; (i) electrically connecting a semiconductor element to the wiring pattern such that the underfill resin is filled between the semiconductor element and the wiring pattern; (j) sealing the semiconductor element with a sealing resin; (k) removing the second carrier tape; and (l) providing an external connection terminal on a portion of the wiring pattern which is exposed from the opening.

According to one or more aspects of the present invention, there is provided a method of manufacturing a semiconductor device. The method comprises: (a) providing a metal foil; (b) laminating a carrier tape on the metal foil; (c) etching the metal foil to form a wiring pattern; (d) providing an underfill resin on the wiring pattern; (e) electrically connecting a semiconductor element to the wiring pattern such that the underfill resin is filled between the semiconductor element and the wiring pattern; (f) sealing the semiconductor element with a sealing resin; (g) removing the carrier tape; (h) forming an insulating layer on a surface of the wiring pattern which is exposed by removing the carrier tape; (i) forming an opening through insulating layer; and (j) providing an external connection terminal on a portion of the wiring pattern which is exposed from the opening.

According to the present invention, an extremely thin semiconductor device can be provided. Also, the respective manufacturing steps can be smoothly handled. Accordingly, manufacturing efficiency can be enhanced, and also semiconductor devices can be manufactured at low cost.

Other aspects and advantages of the invention will be apparent from the following description, the drawings and the claims.

### BRIEF DESCRIPTION OF THE DRAWINGS

FIGS. 1A to 1D are cross-sectional views illustrating manufacturing steps of a semiconductor device according to a first embodiment of the invention;

FIGS. 2A to 2D are cross-sectional views illustrating manufacturing steps of the semiconductor device according to the first embodiment;

FIGS. 3A to 3C are cross-sectional views illustrating manufacturing steps of the semiconductor device according to the first embodiment;

FIGS. 4A to 4D are cross-sectional views illustrating manufacturing steps of a semiconductor device according to a second embodiment of the invention;

FIGS. 5A to 5D are cross-sectional views illustrating manufacturing steps of the semiconductor device according to the second embodiment;

FIGS. 6A to 6E are cross-sectional views illustrating manufacturing steps of a semiconductor device according to a third embodiment of the invention;

FIGS. 7A to 7D are cross-sectional views illustrating manufacturing steps of the semiconductor device according to the third embodiment;

FIGS. 8A to 8D are cross-sectional views illustrating manufacturing steps of the semiconductor device according to the third embodiment;

FIG. 9 is a cross-sectional view illustrating the related-art semiconductor device; and

FIG. 10 is a cross-sectional view illustrating the related-art semiconductor device.

### DETAILED DESCRIPTION OF EXEMPLARY EMBODIMENT OF THE INVENTION

### First Embodiment

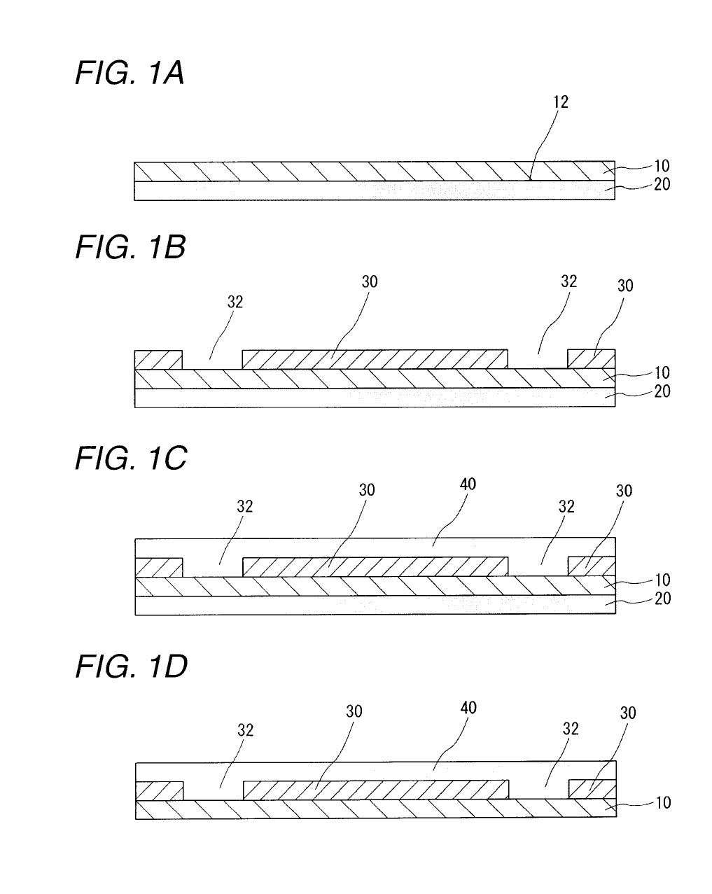

Hereinafter, an exemplary embodiment of the present invention will be now described with reference to the drawings. FIGS. 1A to 3C are cross-sectional views illustrating manufacturing steps of a semiconductor device according to the first embodiment. Although FIGS. 1A to 3C each illustrate a single semiconductor device, it is apparent that plural semiconductor devices can simultaneously be manufactured by mounting a plurality of semiconductor elements on a wiring pattern.

First, as illustrated in FIG. 1A, a first carrier tape 20 is bonded to a copper foil 10 which is a metal foil, so that the copper foil 10 and the first carrier tape 20 are stacked. The present embodiment employs a copper foil 10 having a thickness of about 12 μm to about 15 μm. A first carrier tape 20 is formed on a shiny surface 12 (i.e., a high-smoothness side surface) of the copper foil 10.

A carrier tape having a base material constituted by a polyethylene terephthalate (PET) film, on one side surface of which an acrylic adhesive agent is applied, is used as the first carrier tape 20 according to the present embodiment. The use of the acrylic adhesive agent is advantageous in that the first carrier tape 20 can easily be peeled off and the adhesive does not remain on the copper foil 10 when the first carrier tape 20 is removed later.

Next, as illustrated in FIG. 1B, a solder resist 30 serving as an insulating layer is formed on the copper foil 10. According to the present embodiment, an opening 32 is formed by irradiating laser light onto a portion of the solder resist 30 after the solder resist 30 of the film type is formed thereon.

Next, as illustrated in FIG. 1C, a second carrier tape 40 is laminated on one surface of the solder resist 30. The second carrier tape 40 can be laminated using, e.g., a roll laminator. The second carrier tape 40 can be laminated by being pushed with a roller so as to follow the shape of the surface of the solder resist 30. Thus, as illustrated in FIG. 1C, the second carrier tape 40 is embedded into (or filled in) the opening 32. The present embodiment employs the second carrier tape 40 having a configuration similar to that of the first carrier tape 20.

After the second carrier tape 40 is laminated onto the surface of the solder resist 30, the first carrier tape 20 is removed (see FIG. 1D). The first carrier tape 20 can manually be removed.

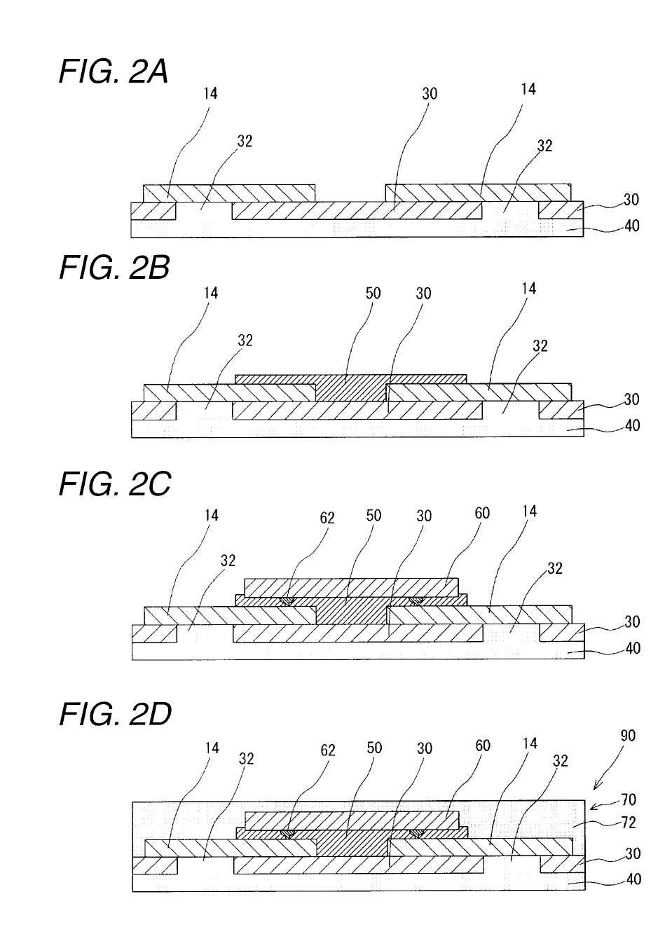

Next, as illustrated in FIG. 2A, a laminated body of the copper foil 10, the solder resist 30, and the second carrier tape 40 is flipped such that the copper foil 10 is placed at the upper side of the laminated body. Subsequently, the patterning of the copper foil 10 is performed by a subtractive method. Thus, a wiring pattern 14 is formed.

Next, as illustrated in FIG. 2B, an underfill resin 50 is provided by affixing a resin sheet, such as a nonconductive film, to a certain portion of the wiring pattern 14. An anisotropically electrically conductive resin film or a die-attachment film can be used as a resin sheet constituting the underfill resin 50, instead of the nonconductive film.

Next, as illustrated in FIG. 2C, a semiconductor element 60 on which bumps 62 serving as electrodes are formed is mounted facedown on the underfill resin 50 such that the bumps 62 are pressed against the underfill resin 50. Thus, the semiconductor element 60 and the wiring pattern 14 are electrically connected to each other by causing the bumps 62 to penetrate through the underfill resin 50, and the bumps 62 and the wiring pattern 14 are connected directly to each other.

Next, as illustrated in FIG. 2D, the wiring pattern 14, the underfill resin 50, and the semiconductor element 60 (more specifically, a side surface on which the semiconductor element 60 is mounted) are resin-molded with a sealing resin 72. Thus, a sealing rein portion 70 is formed. It is advantageous to use a transfer molding apparatus when the sealing resin portion 70 is formed.

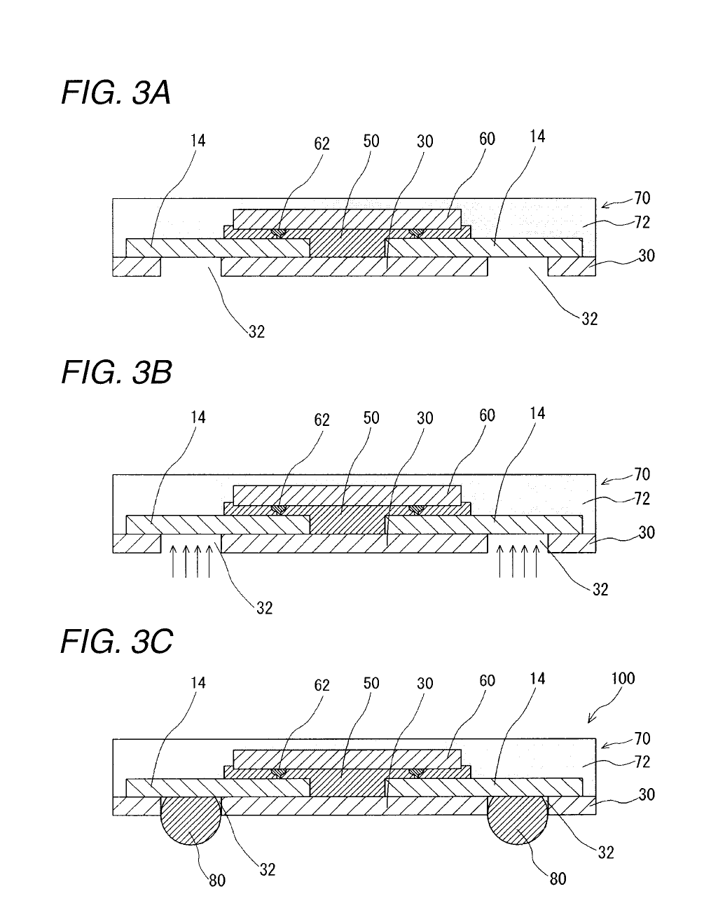

Next, as illustrated in FIG. 3A, the second carrier tape 40 is removed from the resin-sealed laminated body 90. The second carrier tape 40 also can be peeled off manually and easily. As described above, an acrylic adhesive agent is used as the adhesive agent for the second carrier tape 40. Thus, the second carrier tape 40 can easily be peeled off. However, sometimes, the adhesive agent is changed in nature by being heated when the laminated body 90 is resin-sealed. Thus, the adhesive or the changed adhesive may remain on parts of the wiring pattern 14, which are to be exposed from the openings 32 in the solder resist 30. In such a case, each exposed surface (i.e., each connection pad surface) of the wiring pattern 14 (i.e., connection pads) can be washed by performing plasma processing thereon, as illustrated in FIG. 3B. Argon plasma etching or oxygen plasma etching can be used as the plasma processing.

Upon completion of washing the portions of the wiring pattern 14, which are exposed from the opening 32, external connection terminals 80 such as solder bumps are provided to the exposed portions of the wiring pattern 14. Thus, a semiconductor device 100 illustrated in FIG. 3C can be obtained. The semiconductor device 100 is separated by, e.g., a dicer into individual pieces, as occasion demands.

In the semiconductor device 100 according to the present embodiment, the wiring pattern 14 is directly formed on the insulating layer 30. That is, the semiconductor element 60 is pushed against the underfill resin 50 provided on each region of the wiring pattern 14. Then, the bumps 62 serving as the electrodes of the semiconductor element 60 are caused to penetrate through the underfill resin 50. Thus, the semiconductor element 60 is mounted thereon so as to be electrically connected to the wiring pattern 14. Consequently, the sealing resin portion 70 is formed to seal the semiconductor element 60, the underfill resin 50, and a part of the wiring pattern 14. Then, the semiconductor device 100 is formed by providing the external connection terminals 80 to the portions of the wiring pattern 14, which are exposed from the openings 32 in the insulating layer 30, respectively. Accordingly, the semiconductor device 100 having extremely thin thickness can be formed, as compared with the related-art semiconductor device which has the substrate and is manufactured by the flip-chip connection method.

### Second Embodiment

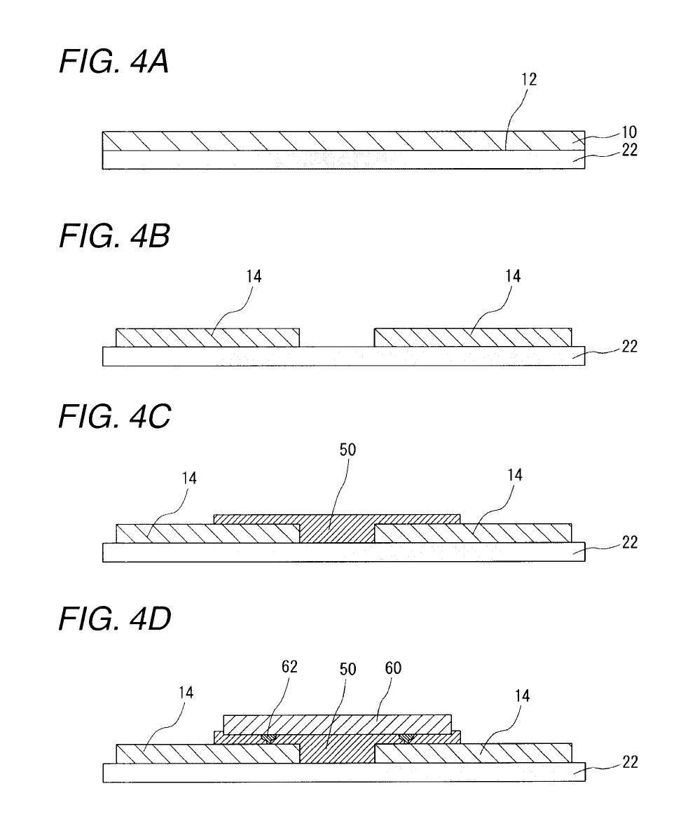

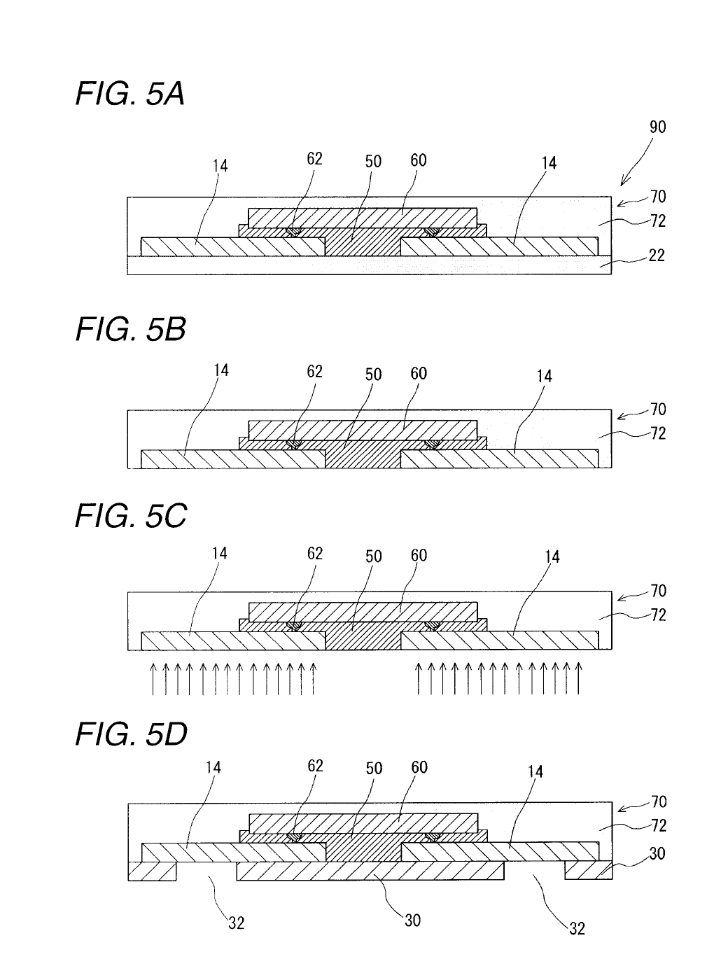

Another manufacturing method for the semiconductor device 100 according to the first embodiment illustrated in FIG. 3C will be now described. FIGS. 4A to 5D are cross-sectional views illustrating manufacturing steps for the semiconductor device 100 according to a second embodiment of the invention.

First, as illustrated in FIG. 4A, a carrier tape 22 is laminated onto a shiny surface 12 of the copper foil 10. The copper foil 10 is formed such that the thickness of the copper foil 10 is in a range from about 12 μm to about 15 μm. A carrier tape having a base material constituted by a PET film, on one surface of which an acrylic adhesive agent is applied, is used as the carrier tape 22, similarly to the first and second carrier tapes 20 and 40.

Next, patterning is performed on the copper foil 10 by the subtractive method to form the wiring pattern 14, as illustrated in FIG. 4B.

Next, as illustrated in FIG. 4C, the underfill resin 50 is formed by affixing a resin sheet, such as a nonconductive film, to a certain region of the wiring pattern 14. An anisotropically electrically conductive resin film or a die-attachment film can be also used as the resin sheet constituting the underfill resin 50, instead of the nonconductive film, similarly to the first embodiment.

Next, as illustrated in FIG. 4D, the semiconductor element 60 on which bumps 62 serving as electrodes are formed is mounted facedown on the underfill resin 50 such that the bumps 62 are pressed against the underfill resin 50, and thus the semiconductor element 60 and the wiring pattern 14 are electrically connected to each other by the bumps 62 penetrating through the underfill resin 50. The bumps 62 and the wiring pattern 14 are directly connected to each other.

Next, as illustrated in FIG. 5A, the wiring pattern 14, the underfill resin 50, and the semiconductor element 60 (more specifically, a surface on which the semiconductor element 60 is mounted) are resin-molded with a sealing resin 72. Thus, a sealing rein portion 70 is formed. It is advantageous to use a transfer molding apparatus when the sealing resin portion 70 is formed.

Next, as illustrated in FIG. 5B, a second carrier tape 22 is removed from the resin-sealed laminated body 90. The second carrier tape 22 also can be peeled off manually and easily. As described above, an acrylic adhesive agent is used as the adhesive agent for the second carrier tape 22. Thus, the second carrier tape 22 can easily be peeled off. However, sometimes, the adhesive or an adhesive component changed in nature by being heated remains on the laminating surface of the carrier tape 22, which is connected to the wiring pattern 14. Accordingly, each surface (inevitably including a surface of each connection pad) of the wiring pattern 14 (i.e., each connection pad), which is exposed by removing the carrier tape 22, can be washed by performing plasma processing thereon, as illustrated in FIG. 5C. Argon plasma etching or oxygen plasma etching can be used as the plasma processing.

After performing plasma processing (i.e., washing processing) on the wiring pattern 14, the solder resist 30 serving as an insulating layer is formed on the bottom surface of the wiring pattern 14. At that time, openings 32 are formed in respective portions of the solder resist 30, to each of which the external connection terminal 80 is to be provided.

The present embodiment also uses the solder resist 30 formed like a film as an insulating layer. Further, the openings 32 are formed by irradiating certain portions of the solder resist 30 with laser light.

As illustrated in FIG. 5D, the external connection terminals 80, such as solder bumps, are respectively provided to portions of the wiring patterns 14 which are exposed from the openings 32. Thus, a semiconductor device 100 having the same configuration as that of the semiconductor device 100 illustrated in FIG. 3C can be obtained by dividing the semiconductor device 100 into individual pieces using, e.g., a dicer, as occasion demands.

According to the manufacturing method for the semiconductor device 100 of the present embodiment, the number of tapes each used as the carrier tape 22 in the manufacturing process can be set at 1. Thus, the shortening of the manufacturing process, and resource saving are enabled. Consequently, the semiconductor device 100 can be manufactured at low cost.

### Third Embodiment

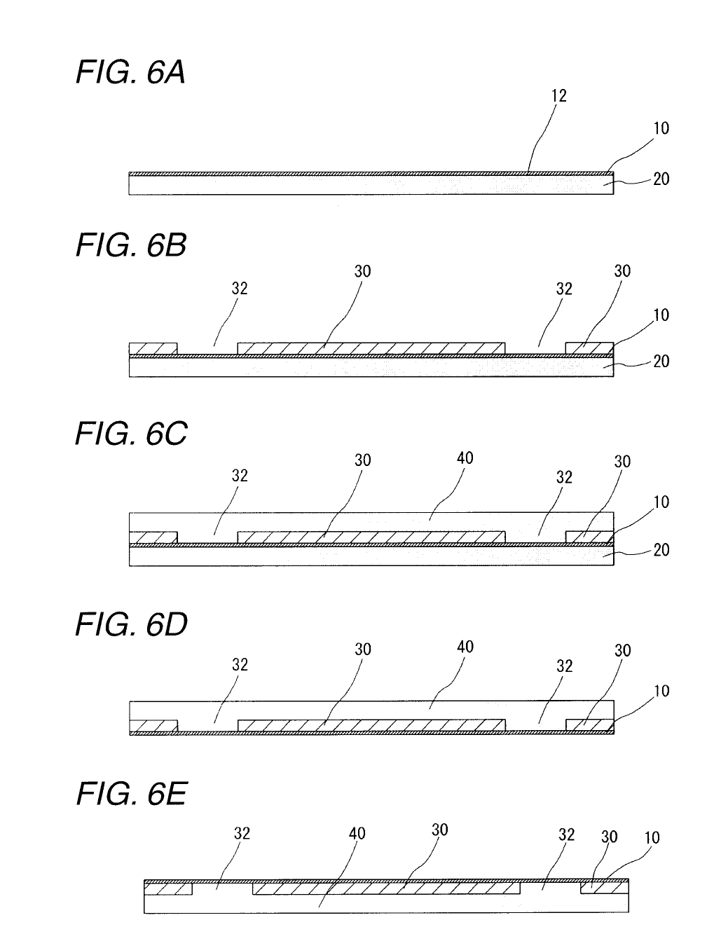

Although the use of the subtractive method at the patterning of the copper foil 10 have been described in the first embodiment and the second embodiment, a wiring pattern 14 can be formed by a semi-additive method, in the case of using some type of a copper foil 1O. In the following description of another embodiment, a third embodiment implemented by applying a semi-additive method to the wiring pattern forming step according to the first embodiment, instead of the subtractive method, is described. FIGS. 6A to 8D are cross-sectional views illustrating manufacturing steps for a semiconductor device according to the third embodiment of the invention.

The present embodiment uses a copper foil 10 having a thickness of about 2 μm to about 3 μm. First, as illustrated in FIG. 6A, the first carrier tape 20 is laminated on the shiny surface 12 of the copper foil 10. Subsequently, the solder resist 30 of the film type is laminated onto the surface of the copper foil 10, as an insulating layer. Then, openings 32 are formed in the solder resist 30 by irradiating laser light onto positions at each of which an external connection terminal is formed (see FIG. 6B). As illustrated in FIG. 6C, the second carrier tape 40 is laminated onto a surface of the solder resist 30. Subsequently, the first carrier tape 20 is removed (see FIG. 6D).

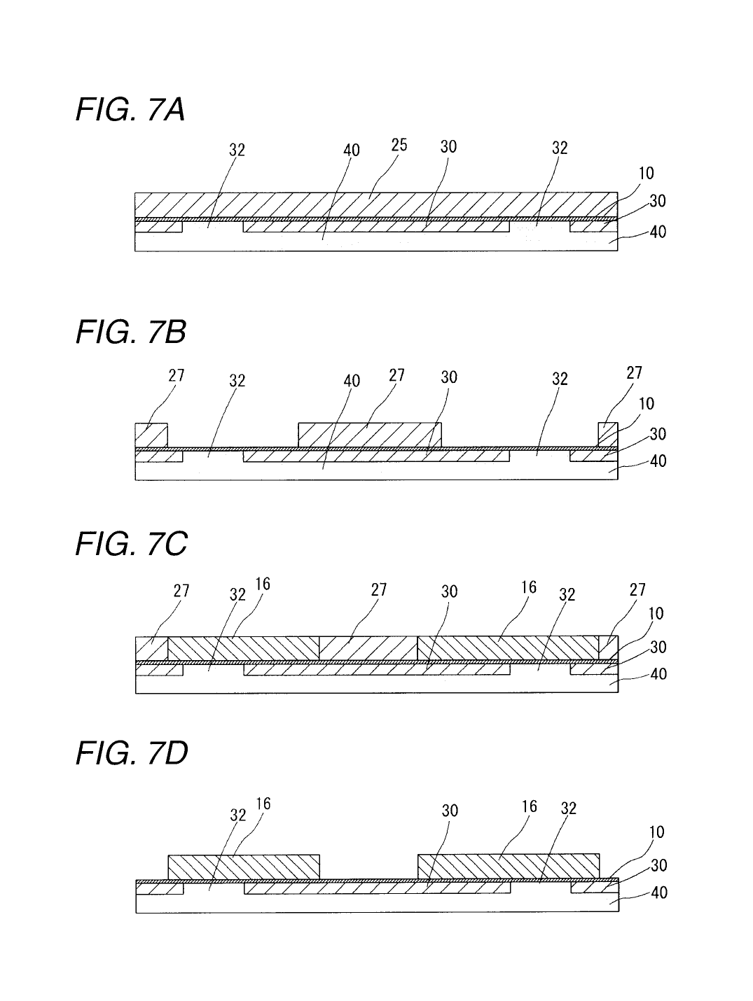

After the first carrier tape 20 is removed, the top surface and the bottom surface of a laminated body including the copper foil 10, the solder resist 30, and the second carrier tape 40, as illustrated in FIG. 6E, are turned over such that the copper foil 10 is placed as an upper side surface. Subsequently, as illustrated in FIG. 7A, a plating resist 25 is laminated onto a surface of the copper foil 10. A photosensitive resin formed like a film is used as the plating resist 25 according to the present embodiment. The plating resist 25 formed on the surface of the copper foil 10 is exposed and developed by a photolithography method. Thus, as illustrated in FIG. 7B, a plating mask 27 is formed. After the plating mask 27 is formed, electrolyte copper plating is performed using the copper foil 10 as a seed metal. Thus, as illustrated in FIG. 7C, copper plating layers 16 are respectively formed in openings of the plating mask 27. After the copper layers 16 are formed, the plating mask 27 is removed by, e.g., wet etching, as illustrated in FIG. 7D.

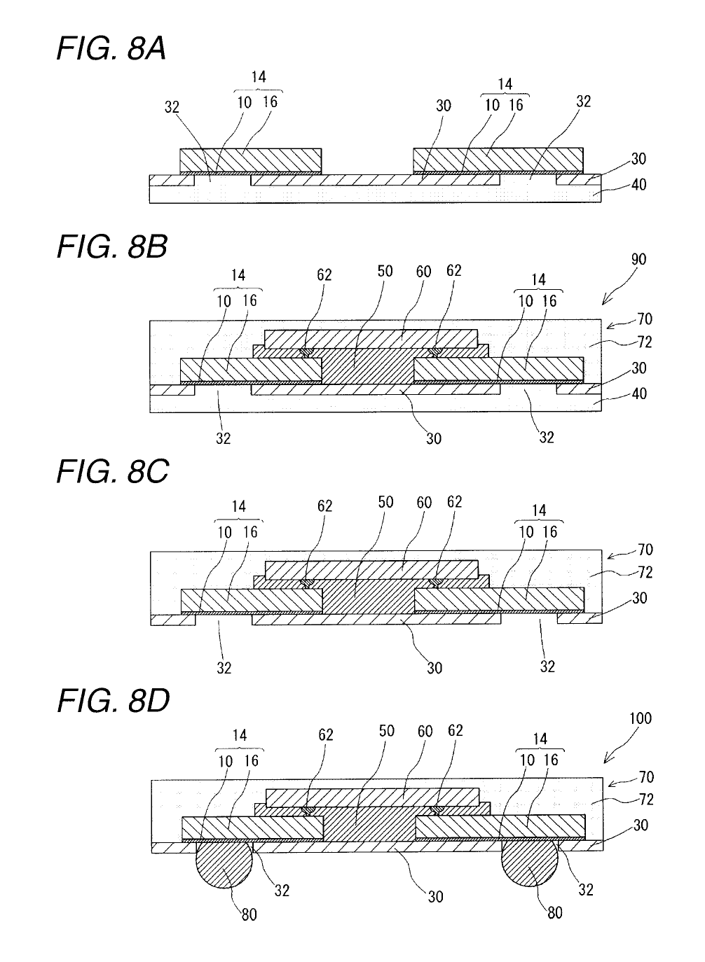

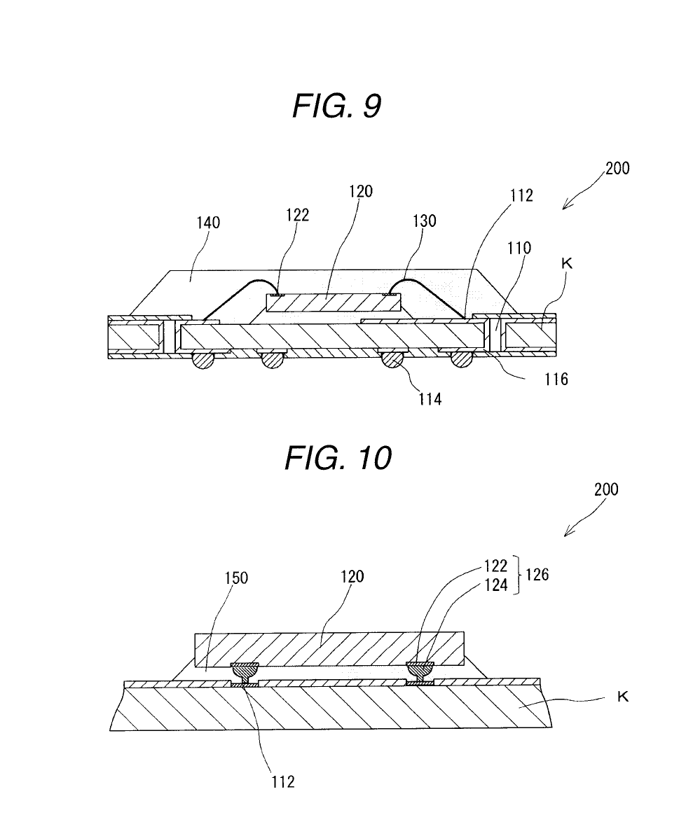

Next, the copper plating layers 16 are separated from one another by etching portions of the copper foil 10, which are covered by the plating mask 27 (i.e., portions of the copper foil 10, which are exposed by removing the plating mask 27). Thus, the wiring pattern 14 illustrated in FIG. 8A is formed. After the wiring pattern 14 is formed, the underfill resin 50 formed of, e.g., a nonconductive film is formed on each given portion of the wiring pattern 14 (i.e., a portion on which the semiconductor element 60 is mounted), as illustrated in FIG. 8B. The semiconductor element 60 on which the bumps 62 are formed is pushed against the underfill resin 50. The bumps 62 are caused to penetrate through the underfill resin 50 so as to be electrically connected to the wiring pattern 14. Thus, the semiconductor element 60 is mounted on the underfill resin 50. Then, the semiconductor element 60 and the wiring pattern 14 are resin-molded with the sealing resin 72. Thus, the sealing resin portion 70 is formed. The respective steps can be performed in a similar manner to the above embodiments. FIG. 8B illustrates a resin sealed laminated body 90.

Subsequently, as illustrated in FIG. 8C, a second carrier tape 40 is removed from the resin-sealed laminated body 90. Even when the second carrier tape 40 is removed, No problems are caused in the subsequent manufacturing process, because of stiffness due to the cured sealing resin portion 70 (i.e., the sealing resin 72). Portions of the wiring pattern 14 are exposed from the openings 32 of the solder resist 30 by removing the second carrier tape 40. Thus, plasma processing (i.e., plasma etching) is performed on the exposed portions of the wiring pattern 14 (i.e., the portions serving as connection pads). Thus, the exposed surfaces of the wiring pattern 14 are cleaned. The plasma processing described in the above embodiments can be also applied to this embodiment. Then, external connection terminals 80 such as solder bumps are provided to the portions (i.e., the connection pads) of the wiring pattern 14, which are exposed from the openings 32 cleaned by the plasma processing. Thus, a semiconductor device 100 illustrated in FIG. 8D can be obtained. Also, the semiconductor device 100 may be divided using a dicer, as occasion demands.

The basic configuration of the semiconductor device 100 according to the present embodiment is similar to those of the semiconductor devices 100 according to the above-described embodiments. However, because the wiring pattern 14 is formed by the semi-additive method, the semiconductor device 100 according to the third embodiment differs from those according to the above embodiments in that because the wiring pattern 14 according to the third embodiment is formed by the semi-additive method, the wiring pattern 14 has a two-layer structure including the copper foil 10 and the copper plating layer 16. Furthermore, the third embodiment is advantageous in that a minute wiring pattern 14 can be formed, as compared with the above embodiments.

In the foregoing description, the semiconductor device 100 according to the invention and the manufacturing method for the semiconductor device 100 have been described in detail based on the embodiments. However, it is apparent that the invention is not limited to the above embodiments. For example, in the foregoing description, the third embodiment has been described in which the wiring pattern 14 is formed by the semi-additive method, instead of the subtractive method. However, it is apparent that the semi-additive method can be used as the method of forming the wiring pattern 14 according to the second embodiment, instead of the subtractive method.

Although the copper foil 10 is used as the metal foil in the above embodiments, it is apparent that other types of metal foils can be used. Further, the thickness of about 12 μm to about 15 μm (in the case of using the subtractive method) and the thickness of about 2 μm to about 3 μm (in the case of using the semi-additive method) are employed as the thickness of the copper foil 10 according to the method of forming the wiring pattern 14. However, it is apparent that the thickness of the metal foil can appropriately be adjusted.

In the first to third embodiments, the method of electrically connecting the wiring pattern 14 and the bumps 62 using a nonconductive film as the under fill resin 50 has been described. However, even in the case of using a die-attachment film as the underfill resin 50, a method similar to the method of using a nonconductive film can be applied thereto. In contrast, in the case of employing an anisotropically electrically conductive film as the underfill resin 50, the wiring pattern 14 and the bumps 62 can be electrically connected to one another via an electrically conductive filler included in the anisotropically electrically film. Thus, it is apparent that a direct connection between the wiring pattern 14 and each of the bumps 62 is unnecessary.

While the present invention has been shown and described with reference to certain example embodiments, other implementations are within the scope of the claims. It will be understood by those skilled in the art that various changes in form and details may be made therein without departing from the spirit and scope of the invention as defined by the appended claims.

What is claimed is:

1. A semiconductor device, comprising:
an insulating layer having an opening therethrough;
a wiring pattern formed on the insulating layer;
an external connection terminal provided on a portion of the wiring pattern which is exposed from the opening;
a semiconductor element flip-chip-mounted on the wiring pattern through a connection portion;
an underfill resin which is filled between the semiconductor element and the wiring pattern to cover the connection portion; and
a sealing resin portion which seals the semiconductor element.

2. The semiconductor device according to claim 1, wherein the underfill resin is formed of a non-conductive film, and
the connection portion is a bump provided on the semiconductor element.

3. The semiconductor device according to claim 1, wherein the underfill resin is formed of an anisotropically-conductive film.

4. The semiconductor device according to claim 1, wherein the wiring pattern is formed of copper.

5. A method of manufacturing a semiconductor device, the method comprising:
(a) providing a metal foil;
(b) laminating a first carrier tape on the metal foil;
(c) forming an insulating layer on the metal foil;
(d) forming an opening through the insulating layer;
(e) laminating a second carrier tape on the insulating layer;
(f) removing the first carrier tape;
(g) etching the metal foil to form a wiring pattern;
(h) providing an underfill resin on the wiring pattern;
(i) electrically connecting a semiconductor element to the wiring pattern such that the underfill resin is filled between the semiconductor element and the wiring pattern;
(j) sealing the semiconductor element with a sealing resin;
(k) removing the second carrier tape; and
(l) providing an external connection terminal on a portion of the wiring pattern which is exposed from the opening.

6. A method of manufacturing a semiconductor device, the method comprising:
(a) providing a metal foil;
(b) laminating a carrier tape on the metal foil;
(c) etching the metal foil to form a wiring pattern;
(d) providing an underfill resin on the wiring pattern;
(e) electrically connecting a semiconductor element to the wiring pattern such that the underfill resin is filled between the semiconductor element and the wiring pattern;
(f) sealing the semiconductor element with a sealing resin;
(g) removing the carrier tape;
(h) forming an insulating layer on a surface of the wiring pattern which is exposed by removing the carrier tape;
(i) forming an opening through insulating layer; and
(j) providing an external connection terminal on a portion of the wiring pattern which is exposed from the opening.

7. The method according to claim 5, wherein step (b) comprises:
laminating the first carrier tape on a shiny surface of the metal foil using an acrylic adhesive resin.

8. The method according to claim 6, wherein step (b) comprises:
laminating the carrier tape on a shiny surface of the metal foil using an acrylic adhesive resin.

9. The method according to claim 5, further comprising:
(m) plasma-etching the portion of the wiring pattern which is exposed from the opening, before step (l) and after step (k).

10. The method according to claim 6, further comprising:
(m) plasma-etching the surface of the wiring pattern which is exposed by removing the carrier tape, before step (h) and after step (g).

11. The method according to claim 5, wherein step (g) comprises: patterning the metal foil by a subtractive method.

12. The method according to claim 6, wherein step (c) comprises: patterning the metal foil by a subtractive method.

13. The method according to claim 5, wherein step (g) comprises: patterning the metal foil by a semi-additive method.

14. The method according to claim 6, wherein step (c) comprises: patterning the metal foil by a semi-additive method.

15. The method according to claim 5, wherein steps (a) to (l) are performed in order.

16. The method according to claim 6, wherein steps (a) to (j) are performed in order.
